(19) United States
(12) Patent Application Publication
(10) Pub. No.: US 2010/0207605 A1
(43) Pub. Date: Aug. 19, 2010

(54) Power supply control apparatus including overcurrent detection circuit

(75) Inventor: Akihiro Nakahara, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/656,522

(22) Filed: Feb. 2, 2010

(30) Foreign Application Priority Data
Feb. 17, 2009 (JP) 33669/2009

(51) Int. Cl. G01R 19/00

(52) U.S. Cl. 324/140 R

(57) ABSTRACT

Provided is a power supply control apparatus including an overcurrent detection circuit with enhanced overcurrent detection accuracy. A power supply control apparatus according to the present invention includes: an output transistor Q1 that controls a current to be supplied to a load; a voltage control circuit that applies a control voltage to a control terminal of the output transistor Q1; and an overcurrent detection circuit. The overcurrent detection circuit includes: a detection MOS transistor Q2 that generates a detection current according to a current flowing through the output MOS transistor Q1; a transistor 9 that generates a current Iref1 based on a bias signal BS1; a transistor 10 that generates a current Iref2 based on a bias signal BS2 that is different from the bias signal BS1, the transistor 10 having a size that is the same as that of transistor 9; and a current mirror circuit that outputs an overcurrent detection signal based on the current Iref1, the current Iref2 and the detection current. Highly-accurate overcurrent detection can be performed by cancelling the effects of the characteristics variations of the transistors in their manufacturing processes and the characteristic variations of the transistors caused by their surrounding temperature conditions.

### CROSS-REFERENCE TO RELATED APPLICATIONS

This application is based upon, claims the benefit of priority of, and incorporates by reference the contents of Japanese Patent Application No. 2009-033669 filed on Feb. 17, 2009.

### BACKGROUND

1. Field of the Invention

The present invention relates to a power supply control apparatus including an overcurrent detection circuit.

2. Description of Related Art

In recent years, vehicles such as automobiles employ what is called an IPD (Intelligent Power Device), which includes switching elements such as power MOSFETs (Metal-Oxide Semiconductor Field-Effect Transistors) or IGBTs (Insulated Gate Bipolar Transistors), and a control circuit, in their electronic control systems as a power supply control apparatus for a load such as a lamp load or a motor load. In a system provided with such load and IPD, for example, upon occurrence of an abnormality such as a terminal short circuit in a terminal section of its electronic control system, a wiring short circuit or a load short circuit, wirings (wire harness), and switching elements (e.g., power MOSFETs) in an IPD may be damaged as a result of an overcurrent flowing therethrough. Accordingly, in general, a circuit (overcurrent protection circuit) for detecting an overcurrent to turn the power MOSFET off is provided as a control circuit for the IPD. Here, in order to safely protect the load and the power MOSFET, there has been a demand for a highly-accurate overcurrent detection circuit.

Recently, as a technique for the overcurrent protection circuit, for example, there has been proposed a power supply control apparatus such as disclosed in Japanese Unexamined Patent Application Publication No. 2005-39573 (reference 1) and U.S. Patent Application Publication No. 2005/0013079 A1 (reference 2), which is a counterpart thereof. FIG. 5 illustrates a power supply control apparatus 500 using an overcurrent detection circuit described in references 1 and 2. The power supply control apparatus 500 includes an output MOS transistor (power MOSFET) MQ1 for switching on/off power supplied from a power supply line 101 to a load 102. A drain terminal of the output MOS transistor MQ1 is connected to a power supply terminal 103 leading to the power supply line 101. Also, a source terminal of the output MOS transistor MQ1 is connected to an output terminal 104 leading to the load 102. Furthermore, the gate terminal of the output MOS transistor MQ1 is connected to a control circuit 105 that outputs a control signal (i.e., applies a control voltage) for switching on/off the output MOS transistor MQ1. The load 102 is connected to a ground line 106 (for example, a frame of the vehicle).

The power supply control apparatus 500 further includes a current detection MOS transistor MQ2 which has a structure similar to the output MOS transistor MQ1 (that is, being different only in dimensions and equal in characteristic per unit channel width). The respective drain terminals of the current detection MOS transistor MQ2 and the output MOS transistor MQ1 are connected in common to the power source terminal 103, and their respective gate terminals are connected in common to the control circuit 105. The power supply control apparatus 500 further includes a current detection resistor MRS connected in series between the source terminals of the current detection MOS transistor MQ2 and the output MOS transistor MQ1.

The power supply control apparatus 500 further includes MOS transistors MQ3 and MQ4 which constitute a current mirror. A source terminal of the MOS transistor MQ3 is connected to a connecting node 107 between the current detection resistor MRS and the current detection MOS transistor MQ2. Furthermore, a gate terminal and a drain terminal of the MOS transistor MQ3 are connected in common to a connecting node 111, and connected in common to the drain terminal of the MOS transistor 109. Meanwhile, a source terminal of the MOS transistor MQ4 is connected to a connecting node 108 between the source terminal of the output MOS transistor MQ1 and the current detection resistor MRS. Furthermore, a gate terminal of the MOS transistor MQ4 is connected in common to the connecting node 111. In addition, a drain terminal of the MOS transistor MQ4 is connected to a drain terminal of a MOS transistor 110 via a connecting node 112. Respective gate terminals of the MOS transistors 109 and 110 are connected in common to a bias signal supply source, and respective source terminals thereof being connected in common to the power source terminal 103. An overcurrent detection signal is output from the connecting node 112.

Here, the case where a wiring connecting with the load 102 comes off for some reason, causing a short circuit with the vehicle's frame, or the output terminal 104 comes into contact with the ground line in a terminal section of an electronic control system will be considered. This case exhibits an abnormal state in which a short circuit occurs between the power supply line 101 and the ground line 106 via the output MOS transistor MQ1, resulting in an overcurrent flowing through the output MOS transistor MQ1. Upon occurrence of such abnormal state, it is necessary to protect the output MOS transistor MQ1 by switching the output MOS transistor MQ1 off or suppressing the current flowing through the output MOS transistor MQ1. An operation for such overcurrent detection will briefly be described below.

The output MOS transistor MQ1 controls the switching on/off of a power supply voltage supplied from the power supply line 101 to the load 102. In other words, the connection between the drain and source terminals of the output MOS transistor MQ1 is controlled via a control signal output from the control circuit 105. The output MOS transistor MQ1 and the current detection MOS transistor MQ2 are structurally similar to each other, and thus, when the current flowing through the output MOS transistor MQ1 increases (for example, 10 A), the current flowing through the current detection MOS transistor MQ2 also increases according to the homothetic ratio (for example, 10000:1) between the output MOS transistor MQ1 and the current detection MOS transistor MQ2 (for example, 10 A/10000=1 mA). Consequently, potential Vs at the connecting node 107 and potential V1 at the connecting node 111 rise. Accordingly, the current flowing through the MOS transistor MQ4 increases. Here, the MOS transistor MQ3 and the MOS transistor MQ4 are structurally similar to each other.

When the current flowing through the MOS transistor MQ4 exceeds a reference current value Iref2 (for example, 50 μA) set by the MOS transistor 110, the overcurrent detection signal output via the connecting node 112 is inverted from a high level to a low level, and thus, it can be determined that an overcurrent state has occurred. Meanwhile, when the current flowing through the output MOS transistor MQ1 is small, the on-current flowing through the MOS transistor MQ4 is smaller than the reference current Iref2. Here, the overcurrent detection signal output via the connecting node 112 is maintained in a high level, and thus, it can be determined that an overcurrent state has not occurred.

Here, the present inventor has found room for further improvement in the power supply control apparatus 500. In the case of the power supply control apparatus 500, in order to detect an overcurrent based on a reference current (for example, Iref2 flowing through the MOS transistor 110), which is a reference to determine whether or not an overcurrent state occurs, and a current flowing through the output MOS transistor MQ1 (for example, a current flowing through the current detection MOS transistor MQ2), it is necessary to adjust the size of each of the transistors (for example, the MOS transistors MQ3, MQ4, 109 and 110). In other words, although they are transistors that are structurally similar to each other, they have different sizes. Thus, such overcurrent detection is affected by characteristic variations of the transistors caused in their manufacturing processes and characteristic variations of the transistors caused by their surrounding temperature conditions.

More specifically, in the case of the power supply control apparatus 500, a common bias signal is supplied to the gate terminals of the MOS transistors 109 and 110. Accordingly, the ratio between the currents flowing through the MOS transistors 109 and 110 depends on the characteristic variation between the MOS transistors 109 and 110. In other words, the reference current (for example, Iref2) needs to be determined relative to the current flowing through the output MOS transistor MQ1 (for example, the current flowing through the current detection MOS transistor MQ2), which is a detection target. Thus, it is necessary to adjust the size of each of the transistors as described above, and the overcurrent detection is sensitive to characteristic variations of the transistors caused in their manufacturing processes and characteristic variations of the transistors caused by their surrounding temperature conditions. Since these characteristic variations cannot completely be eliminated, a new approach is required to provide overcurrent detection with enhanced accuracy.

### SUMMARY

Hereinafter, aspects of the present invention will be described using reference numerals used in the DETAILED DESCRIPTION OF THE PREFERRED EMBODIMENTS section. These reference numerals are provided with parentheses added thereto in order to clarify the correspondence between the recitations in the claims and the DETAILED DESCRIPTION OF THE PREFERRED EMBODIMENTS section. However, these reference numerals should not be used for interpretation of the technical scope of the invention recited in the claims.

An overcurrent detection circuit according to an aspect of the present invention includes a detection transistor (Q2) that generates a detection current according to a current flowing through an output transistor (Q1); a first current source transistor (9) that generates a first reference current based on a first control signal; a second current source transistor (10) that generates a second reference current based on a second control signal that is different from the first control signal, the second current source transistor (10) having a size that is the same as that of the first current source transistor (9); and a current mirror circuit that outputs an overcurrent detection signal based on the first reference current, the second reference current and the detection current.

Also, a power supply control apparatus according to another aspect of the present invention includes an output transistor (Q1) that controls a current to be supplied to a load; a detection transistor (Q2) that generates a detection current according to a current flowing through the output transistor (Q1); a first current source transistor (9) that generates a first reference current based on a first control signal; a second current source transistor (10) that generates a second reference current based on a second control signal that is different from the first control signal, the second current source transistor (10) having a size that is the same as that of the first current source transistor (9); a current mirror circuit that outputs an overcurrent detection signal based on the first reference current, the second reference current and the detection current; and a voltage control circuit (5 or 15) that supplies a control voltage to a control terminal of each of the output transistor (Q1) and the detection transistor (Q2).

The present invention enables provision of a power supply control apparatus including an overcurrent detection circuit capable of highly-accurate overcurrent detection.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a power supply control apparatus 100 including an overcurrent detection circuit according to a first embodiment of the present invention;

FIG. 2 is a power supply control apparatus 200 including an overcurrent detection circuit according to a second embodiment of the present invention;

FIG. 3 is a power supply control apparatus 300 including an overcurrent detection circuit according to a third embodiment of the present invention;

FIG. 4 is a power supply control apparatus 400 including an overcurrent detection circuit according to a fourth embodiment of the present invention; and

FIG. 5 is a power supply control apparatus 500 including an overcurrent detection circuit according to prior art.

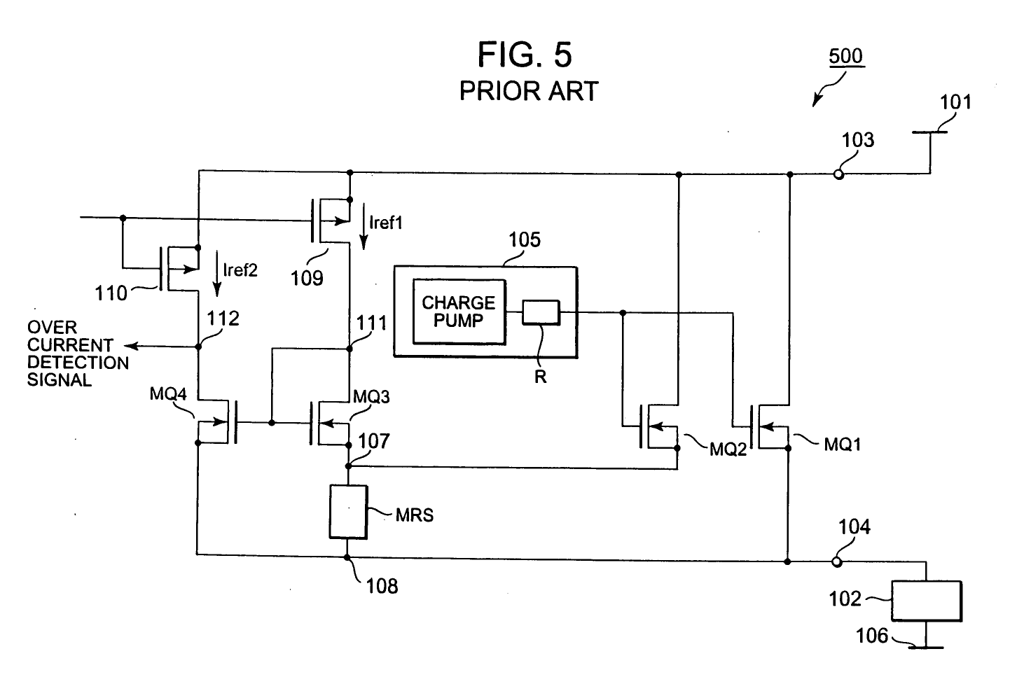

### DETAILED DESCRIPTION OF THE PREFERRED EMBODIMENTS

The invention will be described herein with reference to illustrative embodiments. Those skilled in the art will recognize that many alternative embodiments can be accomplished using the teachings of the present invention and that the invention is not limited to the embodiments illustrated for explanatory purposes.

Hereinafter, specific embodiments of the present invention will be described in detail with reference to the drawings. In the drawings, the same components are provided with the same reference numerals, and for clarity, the same description is not repeated for them where appropriate.

### First Embodiment of the Present Invention

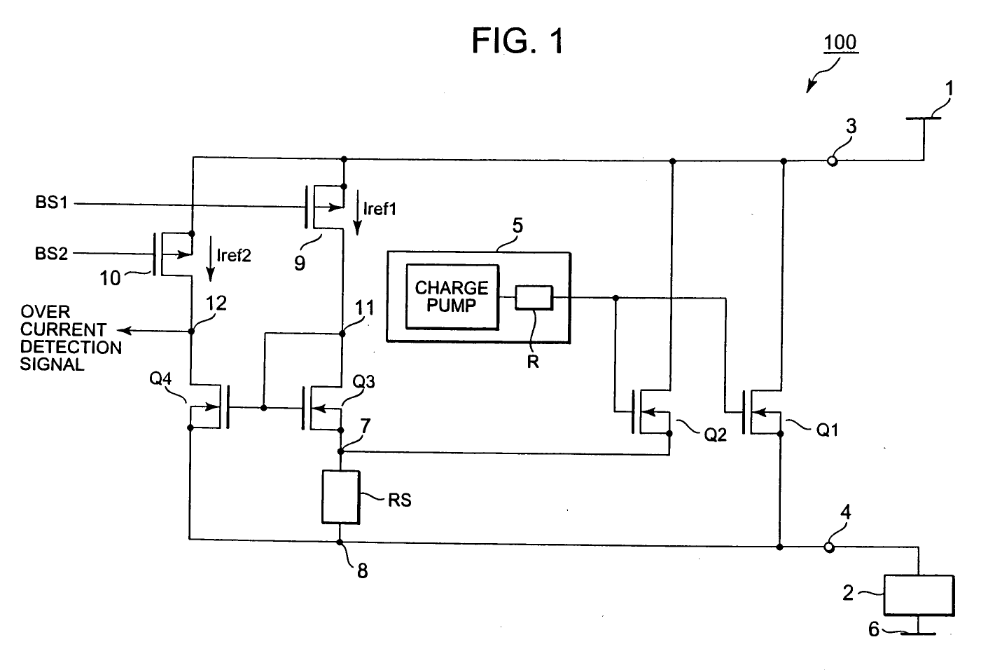

A first embodiment of the present invention will be described with reference to the drawings. As illustrated in FIG. 1, a power supply control apparatus 100 including an overcurrent detection circuit according to a first embodiment of the present invention is an IPD provided with an overcurrent detection function that protects an output transistor against overcurrent.

First, the configuration of the circuit illustrated in FIG. 1 will be described. The circuit illustrated in FIG. 1 has a so-called “high-side switch” configuration in which a high-potential-side connection terminal 3 of the power supply control apparatus 100 is connected to a power supply line 1 and a load 2 is connected between a low-potential-side connection terminal 4 of the power supply control apparatus 100 and a ground line 6. The power supply control apparatus 100 includes an output MOS transistor (output transistor) Q1, a voltage control circuit 5 and an overcurrent detection circuit. The voltage control circuit 5 includes, for example, a charge pump circuit and a gate protection resistor R. The overcurrent detection circuit includes: a transistor (first current source transistor) 9 that outputs a constant current Iref1; a transistor (second current source transistor) 10 that outputs a constant current Iref2; a detection MOS transistor (detection transistor) Q2; a transistor (first mirror transistor) Q3; a transistor (second mirror transistor) Q4; and a current detection resistor RS. Here, the power supply control apparatus 100 have a function that when supplying a power supply voltage from the power supply line 1 to the load 2, detects an overcurrent based on a current flowing through the output MOS transistor Q1. The embodiments of the present invention are described in terms of an example in which the transistors 9 and 10 are P-channel type MOS transistors. Also, the present embodiment is described in terms of an example in which the output MOS transistor Q1, the detection MOS transistor Q2, the transistor Q3 and the transistor Q4 are N-channel type MOS transistors. For convenience, a voltage supplied to the power supply line 1 is referred to as a power supply voltage 1. Also, a voltage supplied to a ground line 6 is referred to as a ground voltage 6.

In the power supply control apparatus 100, the output MOS transistor Q1 controls the switching-on/off of the power supply voltage supplied from the power supply line 1 to the load 2. The drain terminal of the output MOS transistor Q1 is connected to the high-potential-side connection terminal 3 leading to the power supply line 1. The source terminal of the output MOS transistor Q1 is connected to the low-potential-side connection terminal 4 connected to one of terminals of the load 2. Furthermore, the gate terminal of the output MOS transistor Q1 is connected to an output terminal of the voltage control circuit 5 that outputs a control signal (i.e., applies a control voltage) for switching the output MOS transistor Q1 on/off. The other terminal of the load 2 is connected to the ground line 6 (for example, a frame of the vehicle).

The detection MOS transistor Q2 composed of an element that is structurally similar to the output MOS transistor Q1 (i.e., that is different only in dimensions and equal in characteristics per unit channel width). The drain terminal of the detection MOS transistor Q2 is connected to the high-potential-side connection terminal 3. Also, the gate terminal of the detection MOS transistor Q2 is connected to the output terminal of the voltage control circuit 5. Also, the current detection resistor RS is connected in series between the source terminal of the detection MOS transistor Q2 and the source terminal of the output MOS transistor Q1.

The transistor Q3 and the transistor Q4 constitute a current mirror. More specifically, the source terminal of the transistor Q3 is connected to a connecting node 7 between one terminal of the current detection resistor RS and the source terminal of the detection MOS transistor Q2. The gate terminal and the drain terminal of the transistor Q3 are connected in common at the connecting node 11. Furthermore, the drain terminal of the transistor 9 is connected in common to the connecting node 11. Meanwhile, the source terminal of the transistor Q4 is connected to a connecting node 8 between the source terminal of the output MOS transistor Q1 and the other terminal of the current detection resistor RS. Furthermore, the gate terminal of the transistor Q4 is connected in common to the connecting node 11. In addition, the drain terminal of the transistor Q4 is connected the drain terminal of the transistor 10 via a connecting node 12. The gate terminal of the transistor 9 is connected to a supply source (not shown) of a bias signal BS1. Also, the gate terminal of the transistor 10 is connected to a supply source (not shown) of a bias signal BS2, which is different from the supply source of the bias signal BS1. The source terminal of the transistor 9 and the source terminal of the transistor 10 are connected in common to the high-potential-side connection terminal 3. An overcurrent detection signal is output from the connecting node 12.

Each of the transistors Q3 and Q4 composed of an element having the same size to each other. It should be noted that elements having the same size refer to elements designed to have the same size and having, e.g., manufacturing variations caused in their manufacturing processes and temperature characteristics variations, which are substantially equal to each other (hereinafter, the term “element[s] having the same size” is used unless otherwise noted). Similarly, each of the transistor 9 and the transistor 10 composed of an element having the same size to each other.

Next, an operation of the power supply control apparatus 100 will be described. The output MOS transistor Q1 and the detection MOS transistor Q2 are structurally similar to each other. Here, it is assumed that the same gate to source voltage Vgs and the same drain to source voltage Vds are applied to the output MOS transistor Q1 and the detection MOS transistor Q2. In this case, a current flows through the detection MOS transistor Q2 according to the homothetic ratio between the detection MOS transistor Q2 and the output MOS transistor Q1 (according to the ratio of channel widths therebetween). For example, it is assumed that the homothetic ratio between the output MOS transistor Q1 and the detection MOS transistor Q2 is 1000:1. In this case, a current being 1/1000 of the current flowing through the MOS transistor Q1 flows through the detection MOS transistor Q2. In the case of this current ratio, for example, when the current flowing through the output MOS transistor Q1 is 10 A, the current flowing through the detection MOS transistor Q2 is 10 mA.

However, in reality, the power supply control apparatus 100 includes the current detection resistor RS. Accordingly, the current flowing through the detection MOS transistor Q2 is slightly shifted from the above assumption because of a voltage drop caused by the current detection resistor RS. Thus, in the present embodiment, in order to provide highly-accurate overcurrent protection operation, it is desirable to set the voltage drop caused by the current detection resistor RS to a minimum value (for example, 0.1 V or less).

For example, use of a resistance value of around 5Ω for the current detection resistor RS enables setting of the voltage drop caused by the current detection resistor RS to around 0.05 V. Also, use of a resistor made of aluminum for the current detection resistor RS enables reduction in the manufacturing tolerance of the resistance value, that is, enables enhancement of overcurrent detection accuracy.

In the power supply control apparatus 100, as described above, the transistors Q3 and Q4 are elements having the same size. Also, since the current detection resistor RS is connected to the source terminal of the transistor Q3, the transistors Q3 and Q4 have source potentials that are different from each other. Accordingly, when the current flowing through the transistor Q3 is different from the current flowing through the transistor Q4, overcurrent detection can be performed using a desired current value. Therefore, the current (second reference current) Iref2 flowing through the transistor 10 is controlled by a voltage of the bias signal (second control signal) BS2 applied to the gate terminal of the transistor 10. Further, the current (first reference current) Iref1 flowing through the transistor 9 is controlled by a voltage of the bias signal (first control signal) BS1 applied to the gate terminal of the transistor 9. Consequently, for example, an adjustment can made so that the currents Iref1 and Iref2 exhibit the relationship of Iref2>Iref1.

First, the case where no current flows through the output MOS transistor Q1 as a result of the voltage control circuit 5's control to turn the output MOS transistor Q1 off will be described. In this case, no current flows through the detection MOS transistor Q2. Accordingly, the potential Vs of the connecting node 7 does not rise. Also, the potential V1 of the connecting node 11 does not rise. Accordingly, no current flows through the transistor Q4. Consequently, a high-level overcurrent detection signal is output from the connecting node 12. Consequently, it can be determined that the current flowing through the output MOS transistor Q1 is not in an overcurrent state.

Next, the case where a current flows through the output MOS transistor Q1 as a result of the voltage control circuit 5's control to turn the output MOS transistor Q1 on, in a normal state in which no short circuit, etc., occurs will be considered. In this case, it is assumed that a normal current of, for example, 6 A flows through the output MOS transistor Q1. Also, it is assumed that if a current exceeding, for example, 10 A flows through the output MOS transistor Q1, it is determined that the output MOS transistor Q1 is in an abnormal state in which an overcurrent flows.

First, a normal current (for example, 6 A) flows through the output MOS transistor Q1. In this case, a current of 6 mA, for example, flows through the detection MOS transistor Q2 according to the homothetic ratio between the output MOS transistor Q1 and the detection MOS transistor Q2. Accordingly, the potential Vs of the connecting node 7 and the potential V1 of the connecting node 11 rise relative to the potential of the connecting node 8 by the voltage across the current detection resistor Rs. Accordingly, the voltage across the current detection resistor Rs rises to no less than a threshold voltage of the transistor Q4, a current flows through the transistor Q4. However, this current is in less than the current Iref2 (for example, 50 μA) flowing through the transistor 10. Accordingly, a high-level overcurrent detection signal is output from the connecting node 12. Consequently, it can be determined that the current flowing through the output MOS transistor Q1 is not in an overcurrent state.

Meanwhile, the case where, for example, an abnormality such as a short circuit occurs, resulting in an overcurrent exceeding 10 A (for example, 11 A) flows through the output MOS transistor Q1 will be considered. In this case, a current of 11 mA, for example, flows through the detection MOS transistor Q2 according to the homothetic ratio. Accordingly, the potential Vs of the connecting node 7 and the potential V1 of the connecting node 11 further rise relative to the potential of the connecting node 8. Consequently, a current (for example, 55 μA) flows through the transistor Q4. In this case, this current exceeds the current Iref2 (for example, 50 μA) flowing through the transistor 10. Accordingly, the overcurrent detection signal is inverted from a high level to a low level. Consequently, it can be determined that the current flowing through the output MOS transistor Q1 is in an overcurrent state.

Here, an overcurrent detection value Ioc (the current value of the overcurrent detection signal output from the connecting node 12) can be expressed by expression (1) below.

$$\begin{matrix}I o c = \frac{A}{Rs} \cdot ( \sqrt{B \cdot \frac{( \frac{W 3}{L 3} )}{( \frac{W 4}{L 4} )} - 1} ) \cdot ( Vgs 1 - Vt ) \\ = \frac{A}{Rs} \cdot ( \sqrt{B - 1} ) \cdot ( Vgs 1 - Vt )\end{matrix} \qquad ( 1 )$$

wherein A is (the channel width of the output MOS transistor Q1)/(the channel width of the detection MOS transistor Q2); RS is the resistance value of the current detection resistor RS; B is (Iref2/Iref1); L3 is the channel length of the transistor Q3; W3 is the channel width of the transistor Q3; L4 is the channel length of the transistor Q4; W4 is the channel width of the transistor Q4; Vgs1 is the voltage between the gate and source terminals of the transistor Q3; and Vt is a threshold voltage (MOS threshold value) Vt of the transistors Q3 and Q4.

Also, for Vgs1, expression (2) below can be obtained.

Vgs1∝\sqrt{(Iref 1)} (2)

In other words, expression (3) below can be obtained from expressions (1) and (2).

loc∝Vgs∝\sqrt{(Iref 1)} (3)

In other words, the manufacturing tolerance of the overcurrent detection value Ioc is suppressed to the one-half power of a manufacturing tolerance of Iref1.

Each of the transistors 9 and 10 constitutes an element having the same size to each the other. Similarly, each of the transistors Q3 and Q4 constitutes an element having the same size to each other. Accordingly, expression (1) can be expressed by expression (4) below.

$$I o c = \frac{A}{Rs} \sqrt{\frac{{β}_{p} ( W 9 / L 9 )}{{β}_{n} ( W 3 / L 3 )} \cdot } Vref \qquad ( 4 )$$

wherein L9 is the channel length of the transistor 9; W9 is the channel width of the transistor 9; Vref is the potential difference between the bias signal 2 and the bias signal 1; βp=Cox·μp is (the unit area capacity of the channel section of the transistor 9)×(the mobility of the transistor 9); and βn=Cox·μn is (the unit area capacity of the channel section of the transistor Q3)×(the mobility of the transistor Q3).

Here, it can be understood from expression (4) that the overcurrent detection value Ioc does not depend on the threshold voltage Vt of the transistors Q3 and Q4. In other words, the overcurrent detection value Ioc does not depend on the manufacturing tolerance between the transistor Q3 and the transistor Q4 and the temperature. In other words, the effects of the characteristics variation between the transistors Q3 and Q4 caused in their manufacturing processes and the characteristic variation between the transistors Q3 and Q4 caused by their surrounding temperature conditions can be cancelled. Consequently, highly-accurate overcurrent detection can be performed.

Also, for the bias signal BS1 and the bias signal BS2, different potentials can be set. Accordingly, even when each of the transistors 9 and 10 constitutes an element having the same size to each other, the respective currents flowing through the transistors 9 and 10 can be controlled to have different predetermined current values. In other words, since in the conventional power supply control apparatus 500, a common bias signal is supplied to the gate terminals of the MOS transistors 109 and 110, in order to adjust the current values of the first reference current Iref1 and the second reference current Iref2, it is necessary to adjust the transistor sizes of the MOS transistors 109 and 110; however, in the power supply control apparatus 100 according to the present invention, respective proper bias signals are supplied to the gate terminals of the transistors 9 and 10, and thus, each of the transistors 9 and 10 can constitute an element having the same size to each the other. Accordingly, the overcurrent detection value Ioc becomes insensitive to the manufacturing tolerance between the transistors 9 and 10 and the temperature. In other words, the effects of the characteristic variation between the transistors 9 and 10 in their manufacturing processes and the characteristic variation between the transistors 9 and 10 caused by their surrounding temperature conditions can be cancelled. Consequently, highly-accurate overcurrent detection can be performed.

### Second Embodiment of the Present Invention

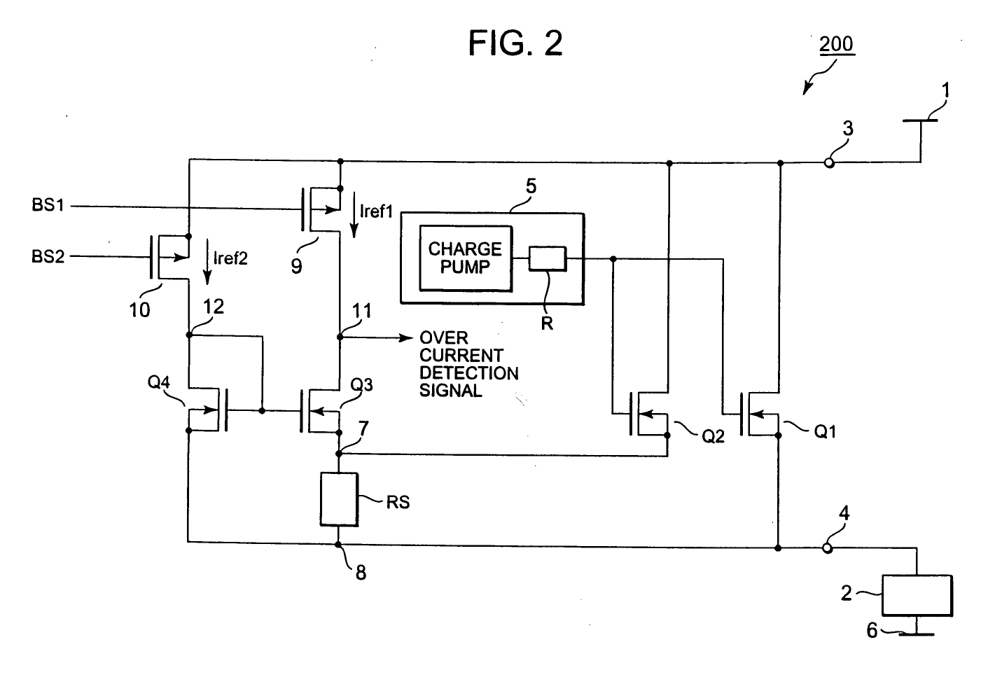

A second embodiment of the present invention will be described with reference to the drawings. As illustrated in FIG. 2, a power supply control apparatus 200 according to a second embodiment of the present invention is different from the power supply control apparatus 100 illustrated in FIG. 1 in the following points. While in the power supply control apparatus 100, the gate terminals of the transistors Q3 and Q4 are connected to the connecting node 11, in the power supply control apparatus 200, they are connected to a connecting node 12. Also, while in the power supply control apparatus 100, an overcurrent detection signal is output from the connecting node 12, in the power supply control apparatus 200, it is output from a connecting node 11. The rest of the circuit configuration is similar to that of the power supply control apparatus 100, and thus, a description thereof will be omitted.

Next, an operation of the power supply control apparatus 200 illustrated in FIG. 2 will be described. For example, upon a current flowing through the output MOS transistor Q1, a current dependent on the homothetic ratio flows through the detection MOS transistor Q2. Accordingly, the potential Vs of the connecting node 7 rises according to the magnitude of the current flowing through the detection MOS transistor Q2.

Meanwhile, the connecting node 12 has a potential based on a voltage drop between the drain and source terminals of the transistor'Q4. This voltage drop depends on the current Iref2 flowing through the transistor Q4 whose gate and drain terminals are connected in common to the connecting node 12 that is connected to the drain terminal of the transistor 10. The potential of this connecting node 12 is supplied to the gate terminal of the transistor Q3.

Here, a current flowing through the transistor Q3 is controlled based on a voltage between the gate and source terminals of the transistor Q3. For example, when the potential Vs of the connecting node 7 rises, the voltage between the gate and source terminals of the transistor Q3 decreases. Accordingly, the current flowing through the transistor Q3 decreases. Here, when the current flowing through the transistor Q3 is larger than the current Iref1 flowing through the transistor 9 (i.e., when a normal current flows), an overcurrent detection signal of a low-level is output from the connecting node 11. Consequently, it can be determined that the current flowing through the output MOS transistor Q1 is not in an overcurrent state.

Meanwhile, the case where the value of the current flowing through the detection MOS transistor Q2 further rises (i.e., an overcurrent flows) will be considered. In this case, the potential Vs of the connecting node 7 further rises. Accordingly, the current flowing through the transistor Q3 further decreases. Here, when the current flowing through the transistor Q3 is smaller than the current Iref1, a high-level overcurrent detection signal is output from the connecting node 11. Consequently, it can be determined that the current flowing through the output MOS transistor Q1 is in an overcurrent state. In other words, the power supply control apparatus 200 outputs an overcurrent detection signal of a low-level in a normal state, and an overcurrent detection signal of a high-level when an overcurrent has been detected. The rest of the operation is similar to that in the case of the power supply control apparatus 100, and thus, a description thereof will be omitted. Such circuit configuration as described above enables provision of an effect similar to that of the first embodiment of the invention.

### Third Embodiment of the Present Invention

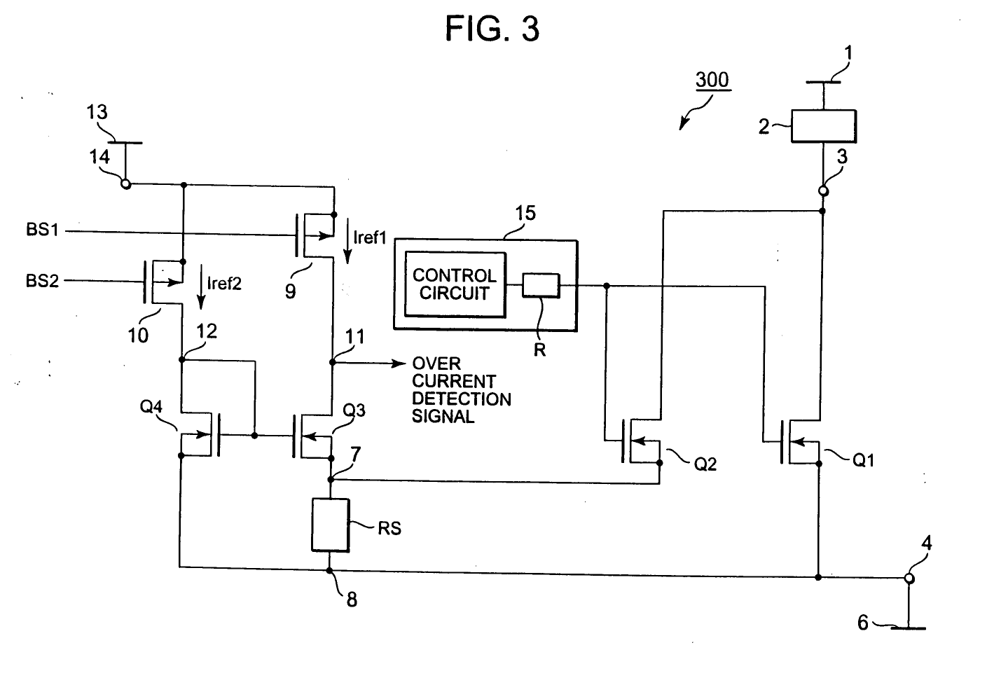

A third embodiment of the present invention will be described with reference to the drawings. As illustrated in FIG. 3, a power supply control apparatus 300 according to a third embodiment of the present invention is different from the power supply control apparatus 200 illustrated in FIG. 2 in the following points. The circuit illustrated in FIG. 2 has a so-called “high-side switch” configuration in which the load 2 is provided between a low-potential-side connection terminal 4 of the power supply control apparatus 200 and a ground line 6. In contrast, the circuit illustrated in FIG. 3 has a so-called “low-side switch” configuration in which the load 2 is provided between the power supply line 1 and the high-potential-side connection terminal 3 of the power supply control apparatus 300, and the low-potential-side connection terminal 4 of the power supply control apparatus 300 is connected to a ground line 6.

Further, in the power supply control apparatus 200, the source terminal of the transistor 9 and the source terminal of a transistor 10 are connected to a high-potential-side connection terminal 3. In contrast, in the power supply control apparatus 300, the source terminal of a transistor 9 and the source terminal of a transistor 10 are connected to a high-potential-side connection terminal 14 of the power supply control apparatus 300. The high-potential-side connection terminal 14 is connected to a power supply line 13. Further, the power supply control apparatus 300 includes a voltage control circuit 15 that outputs a control voltage suitable for the low-side switch configuration, instead of the voltage control circuit 5 of the power supply control apparatus 200. The rest of the circuit configuration is similar to that of the power supply control apparatus 200, and thus, a description thereof will be omitted. Further, an operation of the power supply control apparatus 300 is similar to that of the power supply control apparatus 200, and thus, a description thereof will be omitted. Such circuit configuration as described above enables provision of an effect similar to that of the first embodiment of the invention.

The present invention is not limited the above-described embodiment, and modifications can arbitrarily made as long as such modifications do not deviate from the spirit of the invention. For example, for the power supply control apparatus 300 illustrated in FIG. 3, a description has been made in terms of a circuit configuration in which an overcurrent detection signal is output from a connecting node 11; however, the circuit configuration according to the present invention is not limited to this. For example, a circuit configuration in which an overcurrent detection signal is output from the connecting node 12 can be employed as in the power supply control apparatus 100, instead of the above mentioned circuit configuration illustrated in FIG. 3. In this case, the gate terminal of a transistor Q3 and the gate terminal of a transistor Q4 are not connected to the connecting node 12, but to the connecting node 11 as in the power supply control apparatus 100.

### Fourth embodiment of the present invention

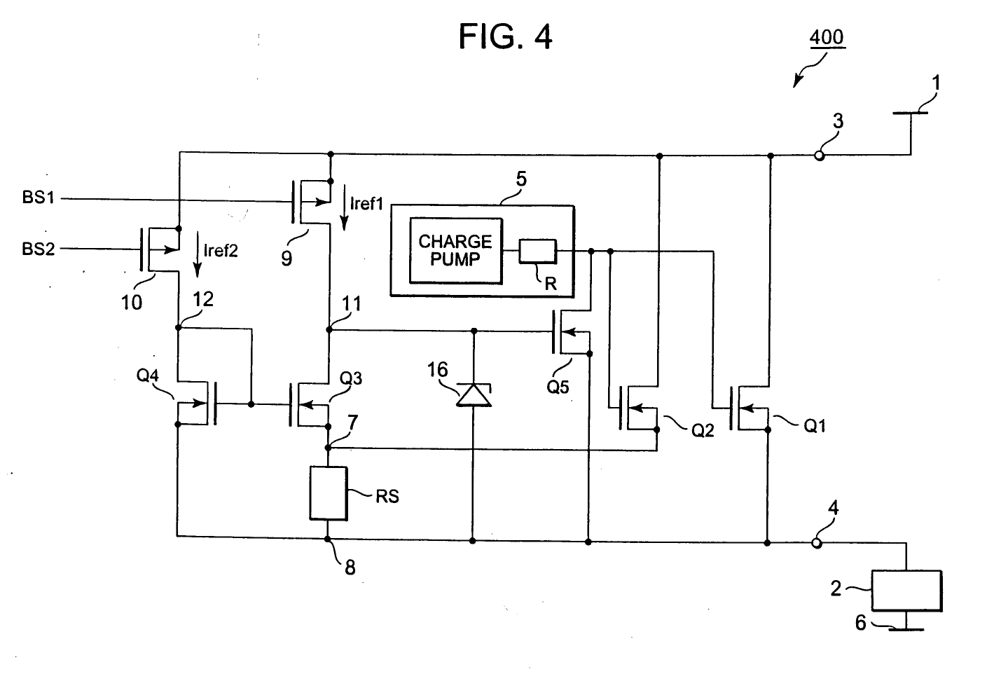

Next, a fourth embodiment of the present invention will be described with reference to the drawings. As illustrated in FIG. 4, a power supply control apparatus 400 according to a fourth embodiment of the present invention includes an overcurrent protection circuit that, upon detection of an overcurrent, suppresses the current flowing through an output MOS transistor Q1 to a given current value (i.e., performs current limitation). More specifically, the power supply control apparatus 400 further includes a transistor (control transistor) Q5 and a Zener diode 16, compared to the power supply control apparatus 200. In the embodiment of the present invention, a case will be described in which the transistor Q5 is an N-channel type MOS transistor.

Both of a source terminal of the transistor Q5 and an anode terminal of the Zener diode 16 are connected to a low-potential-side connection terminal 4. A drain terminal of the transistor Q5 is connected to a connecting node between the gate terminal of the output MOS transistor Q1 and the voltage control circuit 5. Both of a gate terminal of the transistor Q5 and a cathode terminal of the Zener diode 16 are connected to a connecting node 11. The Zener diode 16 is provided to protect the transistors Q3 and Q4 against overvoltage. Accordingly, elements with a lower-voltage structure can be used for the transistors Q3 and Q4. As a result, the area of element can be reduced and the overcurrent detection accuracy can be enhanced. When elements with a higher-voltage structure can be used for the transistors Q3 and Q4, the Zener diode 16 may not be required. The rest of the circuit configuration is similar to that of the power supply control apparatus 200, and thus, a description thereof will be omitted.

Next, an operation of the power supply control apparatus 400 will be described. In terms of operation for outputting an overcurrent detection signal from the connecting node 11 and the previous operation thereof, it is similar to that in the case of the power supply control apparatus 200, and thus, a description thereof will be omitted. In other words, when a normal current flows through the output MOS transistor Q1, an overcurrent detection signal of a low-level is output from the connecting node 11 (the potential of the connecting node 11 is lowered). When an overcurrent flows through the output MOS transistor Q1, an overcurrent detection signal of a high-level is output from the connecting node 11 (the potential of the connecting node 11 is raised).

The power supply control apparatus 400 forms a feedback system as a result of including the transistor Q5. Accordingly, it is possible to implement stable control for preventing overcurrent from flowing through the output MOS transistor Q. Such operation will specifically be described. When an overcurrent flows through the output MOS transistor Q1, the potential of the connecting node 11 is raised. Accordingly, the MOS transistor Q5 exhibits more conductive state. Consequently, the voltage applied between the gate and source terminals of the output MOS transistor Q1 is decreased. In other words, control is performed so that the current flowing through the output MOS transistor Q1 is decreased.

Meanwhile, when a normal current flows through the output MOS transistor Q1, the potential of the connecting node 11 is lowered. Accordingly, the MOS transistor Q5 exhibits less conductive state. Consequently, the voltage applied between the gate and source terminals of the output MOS transistor Q1 is increased. In other words, control is performed so that the current flowing through the output MOS transistor Q1 is increased. As a result of employing a circuit configuration including such feedback system, the power supply control apparatus 400 can stably limit the current flowing through the output MOS transistor Q1. Accordingly, the power supply control apparatus 400 can control the current flowing through the output MOS transistor Q1 with high accuracy, based on a highly-accurate overcurrent detection signal.

The present invention is not limited to the above-described embodiment, and modifications can arbitrarily be made as long as such modifications do not deviate from the spirit of the present invention. For example, for the power supply control apparatus 400 illustrated in FIG. 4, a description has been made in terms of a circuit configuration in which an overcurrent detection signal is output from the connecting node 11; however, the present invention is not limited to this. For example, like in the power supply control apparatus 100 illustrated in FIG. 1, a circuit configuration in which an overcurrent detection signal is output from a connecting node 12 can be employed. In this case, the gate terminals of the transistors Q3 and Q4 are connected not to the connecting node 12, but to the connecting node 11 as in the power supply control apparatus 100. Furthermore, it is necessary to provide a circuit that inverts the overcurrent detection signal output from the connecting node 12, between the connecting node 12 and a connecting node between the gate terminal of the transistor Q5 and the cathode terminal of the Zener diode 16.

As described above, in the power supply control apparatus according to each of the embodiments of the present invention, the transistor Q3 and the transistor Q4 are equal in size to each other. Also, the transistor 9 and the transistor 10 are equal in size to each other. Accordingly, the overcurrent detection value Ioc becomes insensitive to the manufacturing tolerance between the transistor 9 and the transistor 10 and the temperature. Similarly, the overcurrent detection value Ioc becomes insensitive to the manufacturing error between the transistor Q3 and the transistor Q4 and the temperature. In other words, the effects of the characteristic variations of the transistors caused in their manufacturing processes and the characteristic variations of the transistors caused by their surrounding temperature conditions can be cancelled. Consequently, highly-accurate overcurrent detection can be performed.

More specifically, for the bias signal BS1 and the bias signal BS2, potentials that are different from each other can be set. Accordingly, even where the transistors 9 and 10 are equal in size to each other, the currents flowing through the respective transistors can be controlled to have different current values. In other words, it is not necessary to adjust the sizes of the respective transistors in order to detect an overcurrent based on a single bias signal, which is a reference to determine whether or not an overcurrent state occurs and the current flowing through the output MOS transistor Q1. Accordingly, the overcurrent detection value Ioc becomes insensitive to the manufacturing tolerance between the transistors 9 and 10 and the temperature. Similarly, the overcurrent detection value Ioc becomes insensitive to the manufacturing tolerance between the transistors Q3 and Q4 and the temperature. In other words, the effects of the characteristic variations of the transistors caused in their manufacturing processes and the characteristic variations of the transistors caused by their surrounding temperature conditions can be cancelled. Consequently, highly-accurate overcurrent detection can be performed.

The present invention is not limited to the above-described embodiments, and modifications can be made as long as such modifications do not deviate from the spirit of the present invention. For example, for the above-described embodiments, a description has been made in terms of an example in which the output transistor and the detection transistor are MOSFETs; however, the present invention is not limited to this example, and other switching elements such as IGBTs can be employed. Also, for example, in the above-described embodiments, a description has been made in terms of an example in which the transistors Q3 and Q4 are N-channel MOS transistors; however, the present invention is not limited to this example, and for example, NPN bipolar transistors may be employed for the transistors Q3 and Q4. It is known that where a transistor with a MOS structure is used, the relative accuracy of the transistor is in inverse proportion to the square root of the product of the channel width and the channel length. In other words, where the relative accuracy of a MOS transistor is enhanced, the area may be increased. Meanwhile, where bipolar transistors are used, a higher relative accuracy can be provided even with a small area.

Although the invention has been described above in connection with several preferred embodiments thereof, it will be appreciated by those skilled in the art that those embodiments are provided solely for illustrating the invention, and should not be relied upon to construe the appended claims in a limiting sense.

What is claimed is:

1. An overcurrent detection circuit comprising:
a detection transistor that generates a detection current according to a current flowing through an output transistor;
a first current source transistor that generates a first reference current based on a first control signal;
a second current source transistor that generates a second reference current based on a second control signal that is different from the first control signal, the second current source transistor having a size that is the same as that of the first current source transistor; and
a current mirror circuit that outputs an overcurrent detection signal based on the first reference current, the second reference current and the detection current.

2. The overcurrent detection circuit according to claim 1, wherein:
the current mirror circuit includes
a first mirror transistor connected in series to the first current source transistor,
a second mirror transistor connected in series to the second current source transistor, the second mirror transistor having a size that is the same as that of the first mirror transistor, and
a current detection resistor connected in series to the first current source transistor via the first mirror transistor; and
the detection current is supplied to a connecting node between the first mirror transistor and the current detection resistor.

3. The overcurrent detection circuit according to claim 2, wherein:
the first mirror transistor and the second mirror transistor are N-channel MOS transistors; and
a drain terminal of the first mirror transistor is connected to a gate terminal of the first mirror transistor and a gate terminal of the second mirror transistor, and an overcurrent detection signal is output based on the second reference current and a current flowing through the second mirror transistor.

4. The overcurrent detection circuit according to claim 2, wherein:
the first mirror transistor and the second mirror transistor are N-channel MOS transistors; and
a drain terminal of the second mirror transistor is connected to a gate terminal of the second mirror transistor and a gate terminal of the first mirror transistor, and an overcurrent detection signal is output based on the first reference current and a current flowing through the first mirror transistor.

5. The overcurrent detection circuit according to claim 2, wherein:
the first mirror transistor and the second mirror transistor are NPN bipolar transistors; and
a collector of the first mirror transistor is connected to a base of the first mirror transistor and a base of the second mirror transistor, and an overcurrent detection signal is output based on the second reference current and a current flowing through the second mirror transistor.

6. The overcurrent detection circuit according to claim 2, wherein:
the first mirror transistor and the second mirror transistor are NPN bipolar transistors; and
a collector of the second mirror transistor is connected to a base of the second mirror transistor and a base of the first mirror transistor, and an overcurrent detection signal is output based on the first reference current and a current flowing through the first mirror transistor.

7. The overcurrent detection circuit according to claim 1, wherein the first control signal and the second control signal have potentials that are different from each other.

8. The overcurrent detection circuit according to claim 1, wherein the first current source transistor and the second current source transistor are P-channel MOS transistors.

9. A power supply control apparatus, comprising:
an output transistor that controls a current to be supplied to a load;
a detection transistor that generates a detection current according to a current flowing through the output transistor;
a first current source transistor that generates a first reference current based on a first control signal;
a second current source transistor that generates a second reference current based on a second control signal that is different from the first control signal, the second current source transistor having a size that is the same as that of the first current source transistor;
a current mirror circuit that outputs an overcurrent detection signal based on the first reference current, the second reference current and the detection current; and
a voltage control circuit that supplies a control voltage to a control terminal of each of the output transistor and the detection transistor.

10. The power supply control apparatus according to claim 9, further comprising:
a control transistor that supplies another control voltage to a control terminal of each of the output transistor and the detection transistor, based on the overcurrent detection signal.

11. The power supply control apparatus according to claim 10, wherein:
the control transistor is an N-channel MOS transistor; and
a gate terminal of the output transistor is connected to a drain terminal of the control transistor, a source terminal of the output transistor is connected to a source terminal of the control transistor, and the overcurrent detection signal is supplied to a gate terminal of the control transistor.

12. The power supply control apparatus according to claim 11, further comprising:
a Zener diode including a cathode terminal connected to the gate terminal of the control transistor and an anode terminal connected to the source terminal of the output transistor.

13. The power supply control apparatus according to claim 9, wherein the power supply control apparatus is connected on a high-potential side of a power supply relative to the load.

14. The power supply control apparatus according to claim 9, wherein the power supply control apparatus is connected on a low-potential side of the power supply relative to the load.
